(19) United States
(12) Patent Application Publication
(10) Pub. No.: US 2021/0056871 A1
(43) Pub. Date: Feb. 25, 2021

(54) FLEXIBLE DISPLAY PANEL, AND BENDING DETECTION METHOD THEREOF

(71) Applicant: BOE TECHNOLOGY GROUP CO., LTD., Beijing (CN)

(72) Inventors: Jiangnan Lu, Beijing (CN); Libin Liu, Beijing (CN); Shiming Shi, Beijing (CN)

(73) Assignee: BOE TECHNOLOGY GROUP CO., LTD., Beijing (CN)

(21) Appl. No.: 16/919,503

(22) Filed: Jul. 2, 2020

(30) Foreign Application Priority Data
Aug. 21, 2019 (CN) 201910775171.4

(51) Int. Cl. G09F 9/30; G01B 7/16

(52) U.S. Cl. CPC G09F 9/301; G01B 7/22

(57) ABSTRACT

The embodiments of the present disclosure provide a flexible display panel and a bending detection method of a flexible display panel. The flexible display panel includes a display region and a non-display region. The flexible display panel further includes a bending area for realizing a bending of the flexible display panel, the bending area running through the display region and the non-display region. A bending sensor for detecting a bending change of the flexible display panel is provided in a portion of the bending area in the non-display region.

### CROSS-REFERENCE TO RELATED APPLICATION

This application claims priority of Chinese Patent Application No. 201910775171.4 filed on Aug. 21, 2019 in China National Intellectual Property Administration, the disclosure of which is incorporated herein by reference in entirety.

### TECHNICAL FIELD

Embodiments of the present disclosure relate to the field of display technology, and in particular, to a flexible display panel and a bending detection method of a flexible display panel.

### BACKGROUND

Existing flexible display panels can produce various forms of bending, and the deformation is very flexible. At present, there are various types of flexible display panel control based on the bending state of the flexible display panel, for example, the display screen may be zoomed, page-turned according to the bending state, so the detection of the bending state of the flexible display panel becomes very important.

### SUMMARY

According to an aspect of the present disclosure, there is provided a flexible display panel, comprising a display region and a non-display region;

wherein the flexible display panel further comprises a bending area for realizing a bending of the flexible display panel, the bending area running through the display region and the non-display region,

wherein a bending sensor for detecting a bending change of the flexible display panel is provided in a portion of the bending area in the non-display region.

According to some embodiments of the present disclosure, the bending sensor comprises a first electrode, an insulating layer and a second electrode stacked sequentially; wherein an overlapping area of the first electrode and the second electrode changes with the bending change of the flexible display panel.

According to some embodiments of the present disclosure, a plurality of through holes are provided in the second electrode.

According to some embodiments of the present disclosure, a Young modulus of the first electrode is different from a Young modulus of the second electrode.

According to some embodiments of the present disclosure, the Young modulus of the first electrode is not less than the Young modulus of the second electrode.

According to some embodiments of the present disclosure, the Young modulus of the first electrode is ranged from 250 GPa to 350 Gpa, and the Young modulus of the second electrode is ranged from 40 GPa to 100 Gpa.

According to some embodiments of the present disclosure, each of the through holes has a cross-section of round or oval.

According to some embodiments of the present disclosure, a distance between every two through holes is greater than 2 μm.

According to some embodiments of the present disclosure, a distance between the first electrode and the second electrode is ranged from 300 nm to 700 nm.

According to some embodiments of the present disclosure, a portion of the flexible display panel in the display region comprises:

a substrate;

a shielding layer on the substrate;

a buffer layer covering the shielding layer;

a source-drain metal layer and an active layer on the buffer layer;

a gate insulating layer covering the source-drain metal layer and the active layer; and

a gate layer on the gate insulating layer.

According to some embodiments of the present disclosure, the first electrode and the shielding layer are arranged in a same layer, the second electrode and the gate layer are arranged in a same layer, and the insulating layer comprises the buffer layer and the gate insulating layer stacked with each other.

According to some embodiments of the present disclosure, it further comprises: a detection circuit provided in the non-display region and configured to read a capacitance value between the first electrode and the second electrode detected by the bending sensor, and determine a bending state of the bending area according to a change in the capacitance value.

According to some embodiments of the present disclosure, the flexible display panel comprises a plurality of said bending sensors, and the plurality of bending sensors are symmetrically arranged in the bending area on both sides of the display region.

According to some embodiments of the present disclosure, the detection circuit is configured to determine the bending state of the bending area according to a change of an average value of the capacitance values of two of the bending sensors.

According to some embodiments of the present disclosure, the non-display region is provided at a periphery of the display region, and the bending sensor is provided at an end of the bending area.

According to another aspect of the present disclosure, there is provided a bending detection method of a flexible display panel, for detecting a bending state of the flexible display panel according to any one of the above embodiments, the method comprising:

obtaining a capacitance value detected by the bending sensor every preset time; and

determining the bending state of the bending area of the flexible display panel according to a change of the capacitance value.

According to some embodiments of the present disclosure, a plurality of said bending sensors are symmetrically arranged in the bending area on both sides of the display region,

the obtaining a capacitance value detected by the bending sensor every preset time comprises: detecting capacitance values of the bending sensors every preset time; and

the determining the bending state of the bending area of the flexible display panel according to a change of the capacitance value comprises: calculating an average value of the capacitance values; and determining the bending state of the bending area of the flexible display panel according to a change of the average value.

### BRIEF DESCRIPTION OF THE DRAWINGS

In order to more clearly explain the technical solutions of the embodiments of the present disclosure, the following will briefly introduce the drawings used in the description of the embodiments of the present disclosure. Obviously, the drawings in the following description are only some embodiments of the present disclosure. For those of ordinary skill in the art, without paying creative labor, other drawings can also be obtained based on these drawings.

FIG. 1 is a schematic structural diagram of a flexible display panel provided by an embodiment of the present disclosure.

FIG. 2 is a schematic cross-sectional structural diagram of a flexible display panel provided by an embodiment of the present disclosure.

FIG. 3 is a schematic structural diagram of a bending sensor provided by an embodiment of the present disclosure before and after bending.

FIG. 4 is a flowchart of steps of a bending detection method of a flexible detection panel provided by an embodiment of the present disclosure.

FIG. 5 is a flowchart of steps of a bending detection method of a flexible detection panel provided by an embodiment of the present disclosure.

### DETAILED DESCRIPTION OF EMBODIMENTS

The technical solutions in the embodiments of the present disclosure will be described clearly and completely in the following with reference to the drawings in the embodiments of the present disclosure. Obviously, the described embodiments are some of the embodiments of the present disclosure, but not all of the embodiments. All other embodiments obtained by a person of ordinary skill in the art based on the embodiments of the present disclosure without creative efforts fall within the protection scope of the present disclosure.

In the related art, the bending state of the flexible display panel is detected by providing a bending axis in the bending area of the flexible display panel, but the bending axis is not integrated inside the flexible display panel, thus the detection result of the bending state is not accurate enough.

Embodiments of the present disclosure provide a flexible display panel to solve the problem that the detection of the bending state of the flexible display panel by the bending axis provided on the flexible display panel in the related art is not accurate enough.

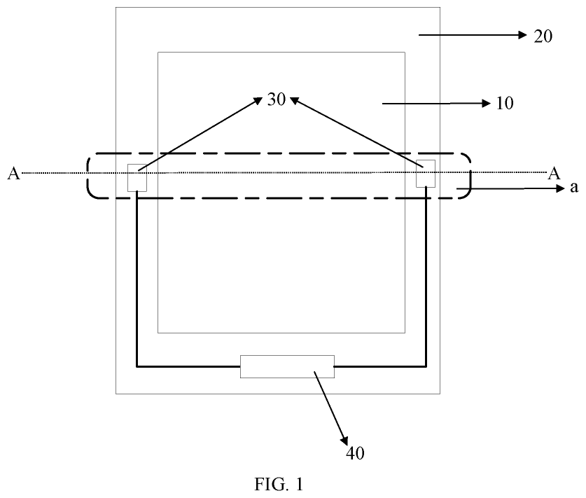

Referring to FIG. 1, a flexible display panel provided by an embodiment of the present disclosure is shown, and the flexible display panel comprises: a display region 10 and a non-display region 20, and the non-display region 20 is provided at the periphery of the display region 10. Bending sensors 30 are provided in a portion of the bending area a in the non-display region 20, and the bending sensor 30 are configured to detect a bending change of the flexible display panel.

In the embodiment of the present disclosure, the bending area a is a narrow area running through the display region 10 and the non-display region 20, and overlaps with the display region 10 and the non-display region 20, respectively. The bending area a is used to realize the bending of the flexible display panel.

In the embodiment of the present disclosure, the flexible display panel may have one bending area or multiple bending areas. When there is one bending area, the flexible display panel is divided into two areas by the bending area, and the two areas are bent along the bending area. When there are multiple bending areas, the flexible display panel can be divided into areas with the number of bending areas plus one, and these areas can be bent along the respective bending areas.

Among them, each bending area has its own bending sensor.

In the embodiments of the present disclosure, the bending sensor may also be integrated in the bending area in the frame.

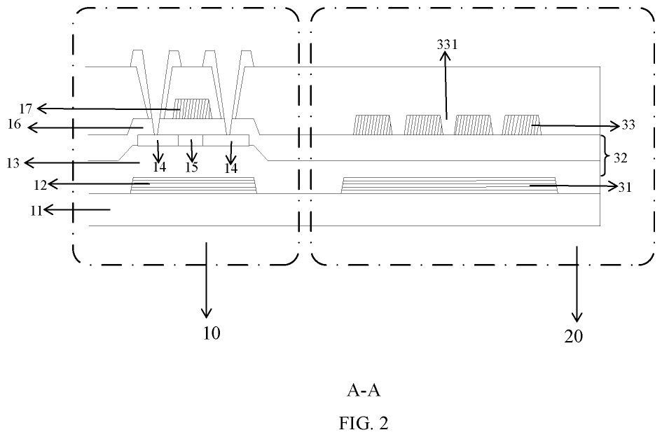

In an embodiment of the present disclosure, referring to FIG. 2, which is a cross-sectional view along A-A in FIG. 1, the bending sensor 30 includes: a first electrode 31, an insulating layer 32, and a second electrode 33 that are stacked sequentially; wherein, an overlapping area of the first electrode 31 and the second electrode 33 changes with the bending change of the flexible display panel.

In the embodiments of the present disclosure, the first electrode and the second electrode may be set in any manner, as long as the overlapping area of the first electrode and the second electrode changes regularly when bending the bending area. The bending change of the flexible display panel detected by the bending sensor specifically refers to the change of the bending state of the flexible display panel represented by the change of the capacitance value of the bending sensor.

In the embodiment of the present disclosure, the first electrode 31 and the second electrode 33 form a capacitor structure, and the capacitance value can be obtained by detection, wherein the larger the overlapping area of the first electrode 31 and the second electrode 33, the greater the capacitance value.

Both the first electrode 31 and the second electrode 33 have ductility. When both the first electrode 31 and the second electrode 33 are bent, the overlapping area of both is increased.

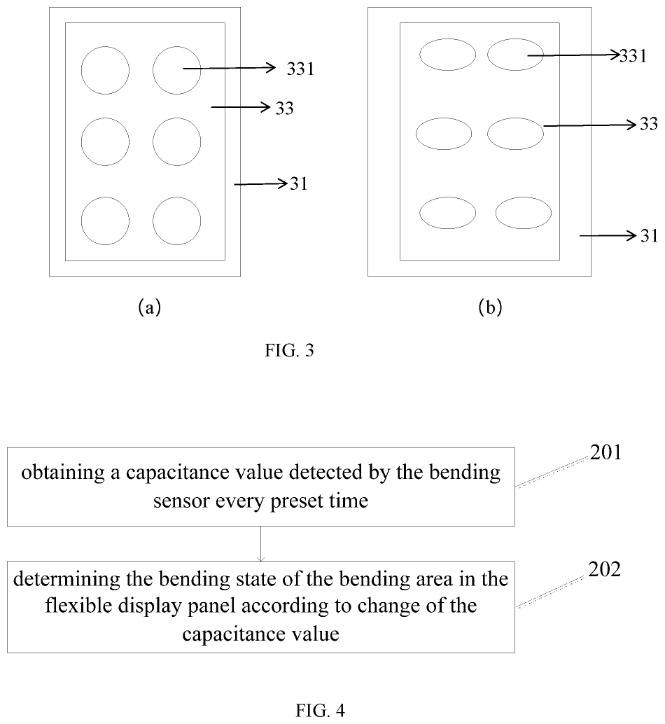

Referring to FIG. 3, which is a top view of the bending sensor 30, the second electrode 33 is provided with a plurality of through holes 331, and the Young modulus of the first electrode 31 is different from the Young modulus of the second electrode 33.

The Young modulus of the first electrode 31 is different from the Young modulus of the second electrode 33, which means that the ductility of the first electrode 31 is different from that of the second electrode 33.

In the embodiments of the present disclosure, the Young modulus of the first electrode 31 is not less than the Young modulus of the second electrode 33.

In the embodiments of the present disclosure, the Young modulus of the first electrode 31 is ranged from 250 GPa to 350 Gpa, and the Young modulus of the second electrode 33 is ranged from 40 GPa to 100 Gpa.

The Young modulus of the first electrode 31 is not less than the Young modulus of the second electrode 33, which means that, under the action of the same force, the deformation amount of the first electrode 31 is less than or equal to the deformation amount of the second electrode, that is, the first electrode is more difficult to bend than the second electrode or is as easy to bend as the second electrode.

In the embodiments of the present disclosure, the through hole 331 has a cross-section of round or oval, and the through hole 331 has a diameter greater than 2 μm.

In the embodiments of the present disclosure, the shape of the through holes and the size of the through holes can be set according to the size of the flexible display panel and the actual needs, which are not limited herein.

Provision of the through hole 331 in the second electrode 33 can be more beneficial to the bending of the bending area and accurately determine the bending state of the bending area. And, when the bending area is bent, the area of the through holes 331 in the second electrode 33 will change, which will affect the overlapping area of the first electrode and the second electrode, for example, when the through hole 331 in the second electrode has a round shape, after bending, the round shape becomes an oval shape, the projection area of the through hole 331 on the first electrode will become smaller, and the second electrode will be stretched, thus the overlapping area of the first electrode and the second electrode increases.

In the embodiments of the present disclosure, a distance between every two through holes is greater than 2 μm.

In the embodiments of the present disclosure, a distance between the first electrode 31 and the second electrode 33 is ranged from 300 nm to 700 nm.

In the embodiments of the present disclosure, a portion of the flexible display panel in the display region 10 comprises: a substrate 11; a shielding layer 12 provided on the substrate 11; a buffer layer 13 covering the shielding layer 12; a source-drain metal layer 14 and an active layer 15 formed on the buffer layer 13; a gate insulating layer 16 covering the source-drain metal layer 14 and the active layer 15; and a gate layer 17 formed on the gate insulating layer 16.

In the embodiments of the present disclosure, the substrate 11 is a flexible substrate, generally made from a polyimide film or a silicon oxide material.

The function of the shielding layer 12 is to block external light from irradiating the screen to affect the channel material of the display region, thereby affecting the characteristics of the display region, and the shielding layer 12 plays a role of light shielding here. The gate layer functions a voltage control, it applies voltage to the gate layer 17 and adjusts the charge distribution in the channel, thereby controlling the switching of the display region.

In the embodiments of the present disclosure, the buffer layer 13 functions to block the shielding layer and the source and drain electrodes, and it is generally a stack of silicon nitride and silicon oxide.

The material of the gate insulating layer 16 is silicon oxide.

In the embodiments of the present disclosure, the width of the bending sensor may be set to 100 μm-200 μm.

In the embodiments of the present disclosure, the first electrode 31 and the shielding layer 12 are arranged in the same layer, the second electrode 33 and the gate layer 17 are arranged in the same layer, and the insulating layer 32 includes the buffer layer 13 and the gate insulating layer 16 arranged in a stack.

The “arranged in the same layer” mentioned herein means that the components in question are formed together in the same process step. The “same layer” neither means that the first electrode and the shielding layer have the same layer thickness or layer height in cross section, nor means that the second electrode and the gate layer have the same layer thickness or layer height in cross section. Moreover, the arrangement of the components in the same layer in question is not limited to that they are at the same vertical height or have the same thickness, and when they are formed of the same patterning process using the same material, they are considered to be arranged in the same layer.

The first electrode 31 and the shielding layer 12 are arranged in the same layer. When the shielding layer 12 is prepared, the first electrode 31 can be prepared without adding a new process to prepare the first electrode.

In the embodiments of the present disclosure, the first electrode 31 and the second electrode 33 may be formed through a sputtering process.

At the same time, the second electrode 33 and the gate layer 17 are arranged in the same layer. When preparing the gate layer 17, the second electrode 33 can be prepared without adding a new process to prepare the second electrode 33.

In the embodiments of the present disclosure, the shape and material of the first electrode 31 can be the same as the shielding layer 12; the material of the second electrode 33 can be the same as the gate layer 17.

In the embodiments of the present disclosure, the materials of the first electrode and the second electrode are conductive metal materials, including one of molybdenum, aluminum, copper, or silver; wherein, the materials of the first electrode and the second electrode are different.

In the embodiments of the present disclosure, it further comprises a detection circuit 40 provided in the non-display region 20 and configured to read a capacitance value between the first electrode 31 and the second electrode 33 detected by the bending sensor, and determine a bending state of the bending area a according to change in the capacitance value.

Referring to FIG. 1, the detection circuit 40 is electrically connected to the bending sensor 30 and is configured to transmit capacitance value and other signals.

The detection circuit can be integrated in a portion of the substrate in the non-display region.

In the embodiments of the present disclosure, referring to FIG. 1, the bending sensors 30 are symmetrically arranged in the bending area a on both sides of the display region 10.

Symmetrical arrangement of two same bending sensors can improve the accuracy of measuring the bending state.

In the embodiments of the present disclosure, the detection circuit 40 is configured to determine the bending state of the bending area a according to change of an average value of the capacitance values of two of the bending sensors

In the embodiments of the present disclosure, when the two bending sensors are the same, the bending state of the bending area a can be determined according to the change of the average value of the capacitance values of the two bending sensors 30 to improve the accuracy of measuring the bending state of the flexible display panel.

In the embodiment of the present disclosure, referring to FIG. 3 (a), it is a top view of a bending sensor in a normal state, the through holes 331 in the second electrode 33 have a round shape. Referring to FIG. 3 (b), it is a top view of the bending sensor as shown in FIG. 3 (a) after bending, the through holes 331 have an oval shape. The area of the through hole 331 becomes smaller, the projection area of the through hole on the first electrode 31 also becomes smaller. The greater the overlapping area of the first electrode 31 and the second electrode 33, the greater the capacitance value of the bending sensor 30 tested by the detection circuit 40.

In the embodiment of the present disclosure, when the bending area a is bent, the through hole 331 will be deformed, and the overlapping area will be changed. The Young modulus of the first electrode and the Young modulus of the second electrode are different, for example, when the Young modulus of the first electrode is greater than the Young modulus of the second electrode, the second electrode 33 is easy to deform, then the capacitance value of the bending sensor 30 is C=εS/d, where ε is a dielectric constant of the insulating layer between the two electrodes, and S is the overlapping area of the two electrodes, and d is a distance between the two electrodes. When bending, the through hole deforms, S changes, and thus the capacitance value changes. The larger the bending angle of the bending area a, the larger the overlapping area of the first electrode and the second electrode, and the larger the capacitance value of the corresponding bending sensor, where the bending state refers to the bending angle. Finally, the capacitance value can be sent to the detection circuit to determine the bending angle.

In the embodiments of the present disclosure, a database may be established through testing in advance, and the database includes: a one-to-one correspondence between the capacitance value and the bending angle. In the test, when the detection circuit detects the capacitance value, the bending state of the flexible display panel can be determined by directly searching the corresponding bending angle in the database.

The flexible display panel provided by the embodiments of the present disclosure includes: the display region and the non-display region. The non-display region is provided at the periphery of the display region; and a bending sensor is provided in a portion of the bending area in the non-display region, and the bending sensor is configured to detect a bending change of the flexible display panel. In the embodiments of the present disclosure, the bending sensor is provided in the bending part of the non-display region. On one hand, the integration in the non-display region can avoid the influence on the display region, on the other hand, the integration inside the bending area can accurately test the bending state of the flexible display panel.

FIG. 4 shows a bending detection method of a flexible display panel provided by an embodiment of the present disclosure, which is applied to the flexible display panel described in any one of the above embodiments. The method includes:

Step 201: obtaining a capacitance value detected by the bending sensor every preset time; and

Step 202: determining the bending state of the bending area in the flexible display panel according to change of the capacitance value.

In the embodiments of the present disclosure, the detection circuit 40 may be used to detect the capacitance value of the bending sensor 30, where the preset time may be a time set by the user as needed, for example, 0.5 s, 1 s, 2 s, or 3 s, etc., which is not limited herein

In the embodiment of the present disclosure, when the bending area a is bent, the through hole 331 will be deformed, and the overlapping area will be changed. The Young modulus of the first electrode and the Young modulus of the second electrode are different, for example, when the Young modulus of the first electrode is greater than the Young modulus of the second electrode, the second electrode 33 is easy to deform, then the capacitance value of the bending sensor 30 is C=εS/d, where ε is a dielectric constant of the insulating layer between the two electrodes, and S is the overlapping area of the two electrodes, and d is a distance between the two electrodes. When bending, the through hole deforms, S changes, and thus the capacitance value changes. The larger the bending angle of the bending area a, the larger the overlapping area of the first electrode and the second electrode, and the larger the capacitance value of the corresponding bending sensor, where the bending state refers to the bending angle. Finally, the capacitance value can be sent to the detection circuit to determine the bending angle.

In the embodiments of the present disclosure, during the bending process, the capacitance value is tested every preset time, and the bending state of the bending area can be obtained in real time.

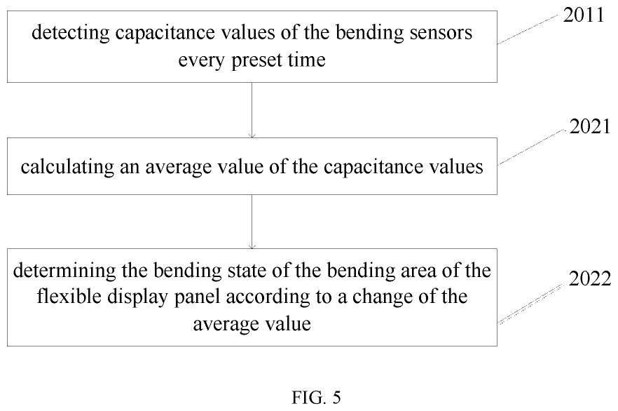

Referring to FIG. 5, when bending sensors are symmetrically arranged in the bending area on both sides of the display region, the Step 201 comprises: step 2011 of detecting capacitance values of the bending sensors every preset time; and the Step 202 comprises: step 2021 of calculating an average value of the capacitance values; and step 2022 of determining the bending state of the bending area of the flexible display panel according to a change of the average value.

In the embodiments of the present disclosure, a bending sensor may be provided at either end of the bending area in the non-display region to improve measurement accuracy of the bending state.

In the embodiments of the present disclosure, a database may be established through testing in advance, and the database includes: a one-to-one correspondence between the capacitance value and the bending angle. In the test, when the detection circuit detects the capacitance value, the bending state of the flexible display panel can be determined by directly searching the corresponding bending angle in the database.

In summary, the bending detection method of the flexible detection panel provided by the embodiments of the present disclosure includes: obtaining a capacitance value detected by the bending sensor every preset time; and determining the bending state of the bending area of the flexible display panel according to a change of the capacitance value. The embodiments of the present disclosure can accurately obtain the bending state of the flexible display panel by detecting the capacitance value of the bending sensor, and the process of acquiring the bending state is simple.

Those skilled in the art can clearly understand that, for the convenience and conciseness of the description, the working process of the components described above can refer to the corresponding process in the foregoing method embodiments, which will not be repeated here.

The above are only the optional embodiments of the present disclosure and are not intended to limit the present disclosure. Any modification, equivalent replacement and improvement made within the spirit and principle of the present disclosure shall be included in the protection scope of the present disclosure.

The above are only specific implementations of the present disclosure, but the protection scope of the present disclosure is not limited to this, and any person skilled in the art can easily think of changes or replacements within the technical scope disclosed in the present disclosure, they should be covered by the protection scope of the present disclosure. Therefore, the protection scope of the present disclosure shall be defined by the claims.

What is claimed is:

1. A flexible display panel, comprising a display region and a non-display region;
wherein the flexible display panel further comprises a bending area for realizing a bending of the flexible display panel, the bending area running through the display region and the non-display region,
wherein a bending sensor for detecting a bending change of the flexible display panel is provided in a portion of the bending area in the non-display region.

2. The flexible display panel according to claim 1, wherein the bending sensor comprises a first electrode, an insulating layer and a second electrode stacked sequentially; wherein an overlapping area of the first electrode and the second electrode changes with the bending change of the flexible display panel.

3. The flexible display panel according to claim 2, wherein a plurality of through holes are provided in the second electrode.

4. The flexible display panel according to claim 3, wherein a Young modulus of the first electrode is different from a Young modulus of the second electrode.

5. The flexible display panel according to claim 4, wherein the Young modulus of the first electrode is not less than the Young modulus of the second electrode.

6. The flexible display panel according to claim 5, wherein the Young modulus of the first electrode is ranged from 250 GPa to 350 Gpa, and the Young modulus of the second electrode is ranged from 40 GPa to 100 Gpa.

7. The flexible display panel according to claim 3, wherein each of the through holes has a cross-section of round or oval.

8. The flexible display panel according to claim 3, wherein a distance between every two through holes is greater than 2 μm.

9. The flexible display panel according to claim 2, wherein a distance between the first electrode and the second electrode is ranged from 300 nm to 700 nm.

10. The flexible display panel according to claim 2, wherein a portion of the flexible display panel in the display region comprises:
a substrate;
a shielding layer on the substrate;
a buffer layer covering the shielding layer;
a source-drain metal layer and an active layer on the buffer layer;
a gate insulating layer covering the source-drain metal layer and the active layer; and
a gate layer on the gate insulating layer.

11. The flexible display panel according to claim 10, wherein the first electrode and the shielding layer are arranged in a same layer, the second electrode and the gate layer are arranged in a same layer, and the insulating layer comprises the buffer layer and the gate insulating layer stacked with each other.

12. The flexible display panel according to claim 2, further comprising: a detection circuit provided in the non-display region and configured to read a capacitance value between the first electrode and the second electrode detected by the bending sensor, and determine a bending state of the bending area according to a change in the capacitance value.

13. The flexible display panel according to claim 12, wherein the flexible display panel comprises a plurality of said bending sensors, and the plurality of bending sensors are symmetrically arranged in the bending area on both sides of the display region.

14. The flexible display panel according to claim 13, wherein the detection circuit is configured to determine the bending state of the bending area according to a change of an average value of the capacitance values of two of the bending sensors.

15. The flexible display panel according to claim 1, wherein the non-display region is provided at a periphery of the display region, and the bending sensor is provided at an end of the bending area.

16. A bending detection method of a flexible display panel, for detecting a bending state of the flexible display panel according to claim 1, the method comprising:
obtaining a capacitance value detected by the bending sensor every preset time; and
determining the bending state of the bending area of the flexible display panel according to a change of the capacitance value.

17. The method according to claim 16, wherein a plurality of said bending sensors are symmetrically arranged in the bending area on both sides of the display region,
the obtaining a capacitance value detected by the bending sensor every preset time comprises: detecting capacitance values of the bending sensors every preset time; and
the determining the bending state of the bending area of the flexible display panel according to a change of the capacitance value comprises: calculating an average value of the capacitance values; and determining the bending state of the bending area of the flexible display panel according to a change of the average value.
